(19) United States
(12) Patent Application Publication
(10) Pub. No.: US 2025/0260410 A1
(43) Pub. Date: Aug. 14, 2025

(54) MACHINE LEARNING ENHANCED ANALOG-TO-DIGITAL CONVERTERS

(71) Applicant: ARIZONA BOARD OF REGENTS ON BEHALF OF ARIZONA STATE UNIVERSITY, Scottsdale, AZ (US)

(72) Inventors: Sumukh Bhanushali, Tempe, AZ (US); Arindam Sanyal, Scottsdale, AZ (US); Debnath Maiti, Tempe, AZ (US); Tushar Gupta, Tempe, AZ (US)

(73) Assignee: ARIZONA BOARD OF REGENTS ON BEHALF OF ARIZONA STATE UNIVERSITY, Scottsdale, AZ (US)

(21) Appl. No.: 19/051,527

(22) Filed: Feb. 12, 2025

Related U.S. Application Data
(60) Provisional application No. 63/553,345, filed on Feb. 14, 2024.

(51) Int. Cl. H03M 1/06

(52) U.S. Cl. CPC H03M 1/0604

(57) ABSTRACT

Enhanced successive approximation register (SAR) analog-to-digital converters (ADCs). Embodiments in accordance with the present disclosure use a supervised machine learning (ML) technique that corrects both static errors, for example, but not limited to, capacitor mismatches, and dynamic errors, for example, but not limited to, due to reference ripple and kickbacks, as well as lower quantization error and comparator thermal noise, using a single correction technique. Embodiments use a low-speed reference ADC to learn a representation of the ADC errors and correct them in the backend.

### CROSS REFERENCE TO RELATED APPLICATIONS

This application claims the benefit of U.S. Provisional Patent Application No. 63/553,345, entitled Machine Learning Enhanced Analog-to-Digital Converters, filed on Feb. 14, 2024, the contents of which are hereby incorporated by reference in their entirety.

### TECHNICAL FIELD

The present disclosure relates to analog-to-digital converters (ADCs), specifically enhanced successive approximation register (SAR) ADCs.

### BACKGROUND

Data converters act as gatekeepers between the physical world in which information is in analog format, and computing devices in which information is processed, analyzed, and stored in digital format for human consumption. The success of many future applications, from emerging communication standards to future highly granular particle detectors, depends on energy-efficient, high bandwidth ADCs. Technology scaling has been the main driver for increasing energy-efficiency of high bandwidth silicon ADCs. High-speed ADC design in advanced technology nodes comes with several challenges including that small devices have thin gate oxides and operate under low supply voltages, e.g., the supply voltage in a 28 nm CMOS node is 0.9V compared to 1.8V in 180 nm node. Reduction in supply voltage might result in the inability to use traditional analog circuit design techniques that rely on high supply voltages. Other challenges include that devices in advanced technology nodes can exhibit static and dynamic errors and mismatches, compared to older technology nodes, and increasing design speed may require an increase in precision needed in meeting timing requirements across different sub-circuits, and an increase in power consumption needed for generating stable supply and reference voltages needed by the ADCs.

To address the above challenges, existing ADCs focus on techniques such as employing highly digital architectures, for example, the use of inverters to create high-gain amplifiers and delta-sigma integrators, and calibration/correction techniques to correct for gain and timing mismatches as well as static and dynamic errors. The highly digital architectures can be sensitive to variations in process, voltage, temperature (PVT) as well as having nonlinear gain which can require complex calibration and/or error correction techniques. Calibration/correction techniques may require prior knowledge or explicit expression of the mechanisms that create non-idealities in ADCs. Increased interactions between different non-ideality-producing mechanisms in advanced technology can limit the accuracy of calibration/correction techniques and/or require complicated algorithms that are challenging to realize on-chip. In addition, power consumption in the highly digital ADCs can be dynamic in nature which imposes requirements on settling speed and ripple of the supply/reference voltage regulators and can increase their power consumption.

Neural networks can learn efficient representation without requiring explicit expressions. This property can be leveraged to learn non-idealities in ADCs from temporal observations of their outputs and suppress these non-idealities. Neural networks have been used to calibrate ADCs, but not for enhancing performance. While a 90-95% accuracy of machine learning (ML) algorithms is acceptable for many applications, such as image processing/computer vision, ADCs need correction algorithms to have accuracies greater than 99.999% for spurious-free-dynamic range (SFDR) >80 dB. Complex ML architectures cannot be employed to improve accuracy since their power and area consumption will far exceed that of the ADC, thus making them less competitive compared to existing calibration/correction techniques. Another critical requirement is that the neural network needs to perform real-time training to correct dynamic errors over the full bandwidth of high-speed ADCs. This imposes conflicting requirements of precision and speed which are not satisfied by current silicon ML accelerators that typically achieve high speed but low precision.

The conflicting requirements of high accuracy and speed, and low power and area has limited the application of ML in the ADC field. A convolutional-neural network with >13,000 trainable parameters that is trained over 10000 epochs has been used to achieve a modest improvement in ADC ENOB from 4-bits to 5.5-bits. The model complexity and large amount of storage requirement has prevented on-chip realization of the neural network and has limited error correction capability. A neural network that consumes similar power as the ADC cannot be used for practical multi-tone inputs since it depends on fitting the input to a single-tone sinusoid to generate ground truth for training the neural network. A split-ADC architecture has been proposed in which neural networks are used to learn errors in two copies of the same ADC by forcing the two ADC outputs to match each other. This technique works if the two ADCs have significantly different transfer functions, and thus, follow different trajectories when given the same input. This condition requires shifting decision boundaries of one of the ADCs which reduces input range of the ADC and precise knowledge of ADC transfer function.

Noise-shaping successive approximation register (NS-SAR) is a hybrid architecture that combines merits of both SAR and delta-sigma ADCs. SAR ADC is energy efficient at medium resolution (˜10-bits) but is limited by thermal noise at high resolution. On the other hand, delta-sigma ADC can achieve high resolution through oversampling, but designing delta-sigma ADCs with high-gain amplifiers is challenging in advanced technology nodes. NS-SAR combines SAR and delta-sigma by embedding a filter inside the SAR loop that integrates residue from prior conversions, thus, effectively realizing a feed-forward delta-sigma with SAR quantizer. While many innovations in the NS-SAR design space have improved noise-shaping, performance of state-of-the-art NS-SAR ADCs is still primarily limited by comparator thermal noise. Apart from NS-SAR, a ring VCO is another popular technique to implement delta-sigma ADC in advanced technology nodes using mostly digital circuits. VCO ADCs convert analog voltage/current-domain input to time-domain and perform time-domain integration and quantization to realize noise-shaping with high energy efficiency. The key limitations of VCO ADCs are limited linearity in converting voltage/current domain signals to time-domain, and high sensitivity to variations in operating conditions and input common-mode. NS-SAR and VCO architectures could be combined to address the limitations of each without requiring calibration.

Referring now to FIG. 1A, shown is a graphical survey of state-of-the-art high-speed single-channel and time-interleaved ADCs. For example, single-channel ADCs have ˜11-bit ENOB for speeds from hundreds of MHz-GHz ranges, while time-interleaved ADCs have ˜8-bit ENOB at 20 GHz and ˜6-bit ENOB at 100 GHz. The regulation of reference voltage enables high-speed SAR ADC operation, while time-interleaved ADCs operate by regulating interleaving mismatches. As shown, time-interleaved ADCs achieve higher bandwidth compared to single-channel ADCs but have lower ENOB. Techniques to address reference ripple employ large decoupling capacitors and on-chip high-speed reference buffers which consume significant area and power. Techniques to reduce the reference ripple include using pre-charged reservoir capacitor, regulating a dynamic reference, neutralizing the charge, and canceling the reference ripple by emulating the ripple with a replica DAC. These techniques require either a large reservoir capacitor, a clean supply voltage or are limited by replica matching. The ADCs employing these reference ripple reduction techniques have limited ENOB of ˜10-bit at hundreds of MHz speed. Single-channel ADCs can reach sampling speeds in GHz range, time-interleaving of multiple sub-ADCs is needed to reach speeds of tens to hundreds of GHz in silicon. The ENOB of time-interleaved ADCs is limited by mismatches (gain, timing, offset, and bandwidth) between the different sub-ADCs. Timing mismatch is a challenge for time-interleaved ADCs. For example, a 9-bit time-interleaved ADC can tolerate 100 femto-second timing mismatches between the sub-ADCs, while an 11-bit time-interleaved ADC can tolerate less than 30 femto-second timing mismatches. It may be undesirable to perform a single track-and-hold for all the sub-ADCs to cancel timing mismatches at high-speeds. Background calibration techniques are digital versus foreground calibration, which is typically analog and involves tuning sampling delay in each sub-ADC. Existing digital calibration techniques typically estimate error due to mismatches by extracting differences in cross-correlation of sub-ADC outputs. Digital calibration techniques require prior knowledge of signal frequency, do not work for multi-input signals, and frequency-domain techniques (shifting/folding/Hilbert transform) typically require high area and high power cost.

Computing-in-memory (CIM) circuits can be used for hardware acceleration of ML models. In some configurations, static random-access memory (SRAM)-based CIM is used to perform massively parallel computation, high energy-efficiency, and easy integration with CMOS integrated circuits. SRAM-CIM circuits can be used for the on-chip neural networks for correcting ADC errors. An ML model includes neural networks that can require GHz throughput and ˜12-bit or higher precision to correct ADC errors.

A challenge in SRAM-CIM is linearity of the multiply and accumulate (MAC) operations output. The sources of nonlinearity include output dependent discharge current through the SRAM bitcell which introduces non-linearity for large MAC outputs, non-linearity of DACs needed to convert multi-bit input activations to analog voltage for applying to SRAM bitcell, input dependent threshold voltage in the pass transistor that connects the SRAM latch to bitline where the MAC is computed. Linearity of MAC output is limited by mismatches in capacitors across the SRAM array as well as quantization error and nonlinearity in converting analog input to binary pulse.

What is needed is a system that leverages ML techniques to learn and correct static and dynamic errors in the background that will lead to single-channel ADCs with, for example, 12-bit ENOB at GHz bandwidth, and time-interleaved ADCs with, for example, 10-bit ENOB at bandwidth >10 GHz.

### SUMMARY

The system and method in accordance with embodiments of the present disclosure use a circuits-informed approach to extract key features from the ADC output to achieve ML accuracies greater than 99.999%. To correct dynamic errors, the ML model extracts frequency information of the input signal, and the ML is trained continuously in the background. To achieve fast convergence of the ML algorithm, the system and method can use root mean square propagation to optimize ML training to update weights of the ML model during backpropagation. Root mean square propagation updates the learning rate for each model weight adaptively. Additionally, to reduce storage requirements, the ML model trains with new predictor and response samples each time.

High-performance ADCs can use an on-chip neural network to continuously correct static and dynamic errors generated from different mechanisms. At least three features are important to the proper functioning of the systems and methods in accordance with embodiments of the present disclosure. The system includes a low-speed ADC with >12-bit ENOB that acts as reference ADC for correcting errors in a high-speed ADC through supervised ML. The low-speed ADC may not need any calibration and is energy-efficient. In embodiments in accordance with the present disclosure, high-speed single-channel (˜1 GHz bandwidth) and time-interleaved (˜10 GHz bandwidth) ADCs use on-chip ML for continuous error correction over the ADC bandwidth.

High-speed ADCs can be used in large-scale and high-granularity neutrino experiments that use arrays of autonomously powered software-radio defined receivers and multi-channel ADCs with high-resolution, >3 GHz bandwidth, and high energy-efficiency. They can also be used in biomedical applications. The low-speed ADC design techniques can be extended for acquisition of physiological signals in wearable devices that need high dynamic range signal acquisition with high energy-efficiency. Still further, the high-speed ADCs can be used in products that are part of the Internet of Things (IoT). ML accelerators, and the circuit techniques to enable them, can be integrated with IoT devices for a wide variety of applications, from predictive maintenance of equipment and vehicles to patient health monitoring. Embedding ML modules inside IoT devices can enable intelligent filtering of data for selective transmission and can address a data deluge issue.

In a system and method in accordance with embodiments of the present disclosure, supervised learning is used in which a low-speed, high resolution reference ADC is used to generate ground truth for training a neural network in real-time. Online training is used in which the neural network is trained with new data at each iteration to reduce on-chip storage. Fast convergence back-propagation algorithms, for example, can be used to increase convergence speed Machine learning in which domain knowledge of data converters is used to create a custom feature set that enables the neural network to learn ADC errors with >99.999% accuracy with a shallow network (1-2 layers) that consumes 30-50% power of the uncorrected ADC. Error-tolerant, mixed-signal compute-in-memory (CIM) techniques are used, for example, to enable an on-chip neural network that can perform inference at the same speed as the ADC.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method for providing analog-to-digital conversion using a first analog-to-digital converter (ADC) and a second ADC. The method may include executing iterated operations including generating ground truth by the first ADC, training a machine learning (ML) model at each of the iterated operations using the ground truth and an uncorrected output from the second ADC to learn to predict errors of the second ADC at sampling points that the first ADC and the second ADC have in common, and modifying the uncorrected output based on the errors predicted by the ML model from to produce a corrected output. Other embodiments of this aspect include corresponding computer systems, apparatus, and computer programs recorded on one or more computer storage devices, each configured to perform the actions of the methods.

Implementations may include one or more of the following features. Modifying the uncorrected output may include computing a difference between the errors and the uncorrected output. The first ADC may include a low speed (≤5 mhz), high resolution (≥11 bits) ADC. Learning to predict errors may include minimizing a loss function, which may include squaring a difference between the uncorrected output and the ground truth, and dividing the squared difference by two. The ML model may include a hidden layer and an output layer. The output layer may include one neuron performing linear regression. The hidden layer may include up to ten neurons and an activation function. The activation function may include tanh, RELU, leaky RELU, or Softmax. The second ADC may include successive approximation register (SAR) logic. Implementations of the described techniques may include hardware, a method or process, or computer software on a computer-accessible medium.

An analog-to-digital converter system of one or more computers can be configured to perform particular operations or actions by virtue of having software, firmware, hardware, or a combination of them installed on the analog-to-digital converter system that in operation causes or cause the system to perform the actions. One or more computer programs can be configured to perform particular operations or actions by virtue of including instructions that, when executed by data processing apparatus, cause the apparatus to perform the actions. The analog-to-digital converter system includes an ADC system executing iterated operations. The ADC system may include a first ADC generating ground truth, a second ADC producing a corrected output, and a ML model trained at each of the iterated operations using the ground truth and an uncorrected output from the second ADC, the trained ML model configured to predict errors of the second ADC at sampling points that the first ADC and the second ADC have in common. The second ADC modifies the uncorrected output based on the errors predicted by the ML model to produce the corrected output. Other embodiments of this aspect include corresponding computer systems, apparatus, and computer programs recorded on one or more computer storage devices, each configured to perform the actions of the methods.

Implementations may include one or more of the following features. The corrected output may include a difference between the errors and the uncorrected output. The first ADC may include a low speed (≤5 mhz), high resolution (≥11 bits) ADC. The training may include minimizing a loss function that may include squaring a difference between the uncorrected output and the ground truth, and dividing the squared difference by two. The ML model may include a hidden layer; and an output layer. The output layer may include one neuron performing linear regression. The hidden layer may include up to ten neurons and an activation function. The activation function may include tanh, RELU, leaky RELU, or Softmax. The second ADC may include SAR logic. Implementations of the described techniques may include hardware, a method or process, or computer software on a computer-accessible medium.

### BRIEF DESCRIPTION OF THE DRAWINGS

The subject matter of the present disclosure is particularly pointed out and distinctly claimed in the concluding portion of the specification. A more complete understanding of the present disclosure, however, may be obtained by referring to the detailed description and claims when considered in connection with the drawing figures, wherein like numerals denote like elements.

FIG. 1A is a graphical representation of state of the art single channel and time-interleaved CMOS ADCs;

FIG. 1B is a schematic diagram of an exemplary enhanced SAR ADC in accordance with embodiments of the present disclosure;

FIG. 2 is a schematic block diagram of an exemplary ML model used for correcting ADC static and dynamic errors;

FIG. 3 is a pictorial representation of a chip layout in accordance with embodiments of the present disclosure;

FIGS. 4A and 4B are graphical representations of the results of applying ML for error correction with a −1.1 dBFs input signal and a −40 dBFs input signal, respectively;

FIG. 5A is a graphical representation of the results of applying ML for error correction with the ML model trained for one frequency and tested on another frequency;

FIG. 5B is a graphical representation of the results of applying ML for error correction varying signal-to-(noise+distortion) ratio (SNDR) and spurious-free dynamic range (SFDR) versus frequency with re-training of the ML model;

FIG. 6A is a graphical representation of the dynamic range of the ADC before and after ML correction;

FIG. 6B is a performance summary of an exemplary chip in accordance with embodiments of the present disclosure;

FIG. 7A is a schematic diagram and associated information of a high resolution incremental delta-sigma ADC with NS-SAR at first stage and VCO as second stage, in accordance with embodiments of the present disclosure, in which noise shaping in the NS-SAR stage high-pas shapes the interstage gain error;

FIG. 7B is a graphical representation of frequency versus amplitude and interstage gain error percentage demonstrating the robustness of the incremental delta-sigma ADC against interstage gain error;

FIG. 7C is a schematic diagram of a single channel ADC showing a supervised ML technique for correction of dynamic and static errors in accordance with embodiments of the present disclosure;

FIG. 7D is a graphical representation of model results demonstrating an ML-based static and dynamic error correction in a 12-bit SAR ADC chip;

FIG. 7E is a schematic diagram of a time-interleaved ADC with ML-based calibration for correcting mismatch between sub-ADCs in accordance with embodiments of the present disclosure;

FIG. 7F is a graphical representation of model results demonstrating correction of gain and timing mismatch error in a time-interleaved ADC;

FIG. 7G-1 is a schematic diagram of a switched-capacitor SRAM-CIM shown for an exemplary SRAM array with weights in accordance with embodiments of the present disclosure;

FIG. 7G-2 is a schematic diagram of a 9T1C SRAM cell in the hidden layer in accordance with embodiments of the present disclosure;

FIG. 7G-3 is a schematic diagram of a 9T1C SRAM cell in the output layer in accordance with embodiments of the present disclosure;

FIG. 7G-4 is a schematic diagram of a tanh( ) activation function hidden layer in accordance with embodiments of the present disclosure;

FIG. 7G-5 is a schematic diagram of read-out circuits for SRAM array with 4-bit weights in accordance with embodiments of the present disclosure;

FIG. 7H is a graphical representation of model results demonstrating relative robustness of the ML error correction in the presence of errors in an analog implementation of tanh( ) activation and capacitor mismatch;

FIG. 8A is a schematic diagram of an error correction circuit in accordance with embodiments of the present disclosure; and

FIG. 8B is a graphical representation of the results of executing the error correction circuit of FIG. 8A.

### DETAILED DESCRIPTION

The detailed description of various embodiments herein makes reference to the accompanying drawings and pictures, which show various embodiments by way of illustration. While these various embodiments are described in sufficient detail to enable those skilled in the art to practice the disclosure, it should be understood that other embodiments may be realized and that logical and mechanical changes may be made without departing from the spirit and scope of the disclosure. Thus, the detailed description herein is presented for purposes of illustration only and not of limitation. For example, the steps recited in any of the method or process descriptions may be executed in any order and are not limited to the order presented. Moreover, any of the functions or steps may be outsourced to or performed by one or more third parties. Furthermore, any reference to singular includes plural embodiments, and any reference to more than one component may include a singular embodiment.

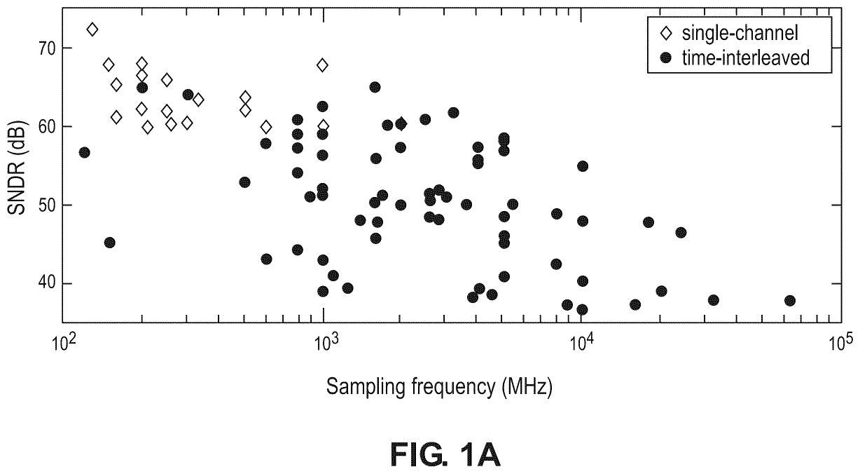

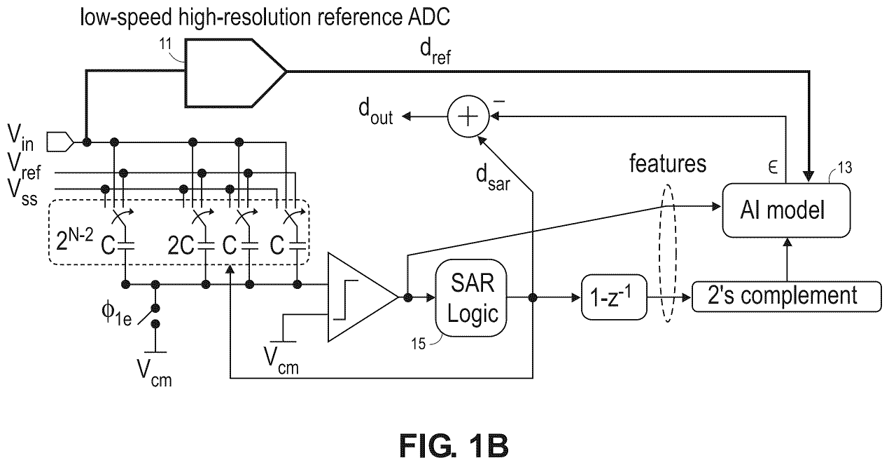

Referring now to FIG. 1B, in some configurations, correcting static and dynamic errors in a SAR ADC using ML can be performed by the circuit of FIG. 1B. A low-speed, high-resolution reference ADC 11 is used to generate ground truth for training the ML model 13. If the main ADC 15 runs at Fₛ and the reference ADC 11 runs at Fₛ/M, the two ADCs will align every M cycles of the main ADC 15. At these aligned sampling instants, the ML model uses outputs of the main ADC to learn a representation of its errors by minimizing the loss function [symbol] =(dₛₐᵣ−D_{ref})²/2 where dₛₐᵣ is uncorrected output of the main ADC and d_{ref} is output of the reference ADC 11. The error predicted by the ML model, E, is then subtracted from dₛₐᵣ to produce the final output, dₒᵤₜ, which mimics the high-resolution reference ADC due to supervised training. Hence, the ML training happens at speed of Fₛ/M whereas the inference happens at Fₛ i.e., every cycle of the main ADC 15.

The ML model uses a set of three features to suppress capacitor mismatch, quantization error and comparator thermal noise, and dynamic errors arising from reference ripple and kickbacks. Assuming that the ADC has N-bits, the SAR output can be written as

$${d}_{sar} = {V}_{in} + Q + {n}_{th} - \frac{{\sum }_{i = 1}^{N} d [ i ] \cdot Δ C [ i ]}{{C}_{dac}} \qquad ( 1 )$$

where

$${d}_{sar} = {\sum }_{i = 1}^{N} {2}^{i - 1} d [ i ] ,$$

Q is quantization error, nₜₕ is the ADC thermal noise comprising of kT/C noise and comparator noise, C_{dac} is the SAR DAC capacitance, and ΔC[i] is the mismatch error associated with i-th DAC capacitor. As shown in Equation (1), capacitor mismatch is added to the ADC output for the bits which are 1. Hence, the ML model can learn the error associated with each capacitor by using the binary bits of the SAR output, d[i] as features.

To suppress quantization error and comparator thermal noise, the systems and methods in accordance with embodiments of the present disclosure adopt a similar approach as stochastic ADCs. In an exemplary configuration, after the SAR conversion is over, the comparator is fired a pre-selected number of times, for example, but not limited to, twenty, and the comparator decisions are used as input features for the ML model to estimate quantization error and comparator noise. Dynamic error in the SAR ADC is proportional to both amplitude and frequency of the input signal and is captured from derivative of the SAR output through digital filtering using (1−z⁻¹). The output of the digital differentiator is converted into a binary stream. Thus, all the features used for training the ML model are binary bits which convert all matrix multiplications in the first hidden layer in the ML model to additions and reduces hardware cost.

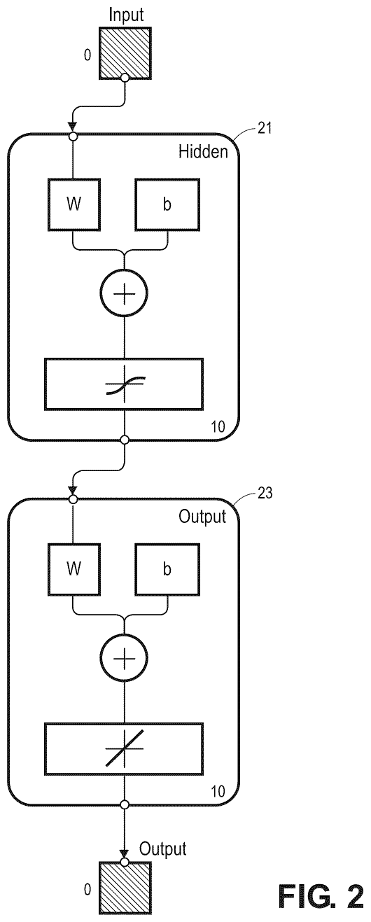

Referring now to FIG. 2, in some configurations, an exemplary ML model in accordance with embodiments of the present disclosure is used. In some configurations, the ML model has a hidden layer 21 with ten neurons and tanh activation, and an output layer 23 with one neuron that performs linear regression. In some configurations, the inputs to the ML model are in binary format. In some configurations, pseudo-code that can be used for training the ML model can include 16 steps as shown.

| | |
|---|---|
| 1: | W1 ← Weight vector hidden layer |
| 2: | W2 ← Weight vector of output layer |
| 3: | Ref ← output of reference ADC |
| 4: | for j < Size(Train set) do |
| 5: | Input ← Trainset(j) |
| 6: | HiddenOuput ← tanh(W1 × Input) |
| 7: | Output ← W2 × HiddenOutput |
| 8: | deltaₒ ← (Output − Ref (j)) |
| 9: | deltaₕ ← ( W2 * deltaₒ) * (1 − HiddenOutput²) |
| 10: | derivₒ ← HiddenOutput × deltaₒ |
| 11: | derivₕ ← Input × deltaₕ |
| 12: | Gₒ ← β × Gₒ + (1 − β) × derivₒ² |
| 13: | Gₕ ← β × Gₕ + (1 − β) × derivₕ² |
| 14: | $W 1 ← W 1 - \frac{α \times {deriv}_{h}}{\sqrt{{G}_{h}}}$ |
| 15: | $W 2 ← W 2 - \frac{α \times {deriv}_{o}}{\sqrt{{G}_{o}}}$ |
| 16: | end for |

In some configurations, the training is online, i.e., the model is trained during iterations with new data points, which obviates the need to store the training dataset. In some configurations, a root mean square propagation algorithm can be used for backpropagation in which the learning rate for model weight is tuned adaptively throughout the training.

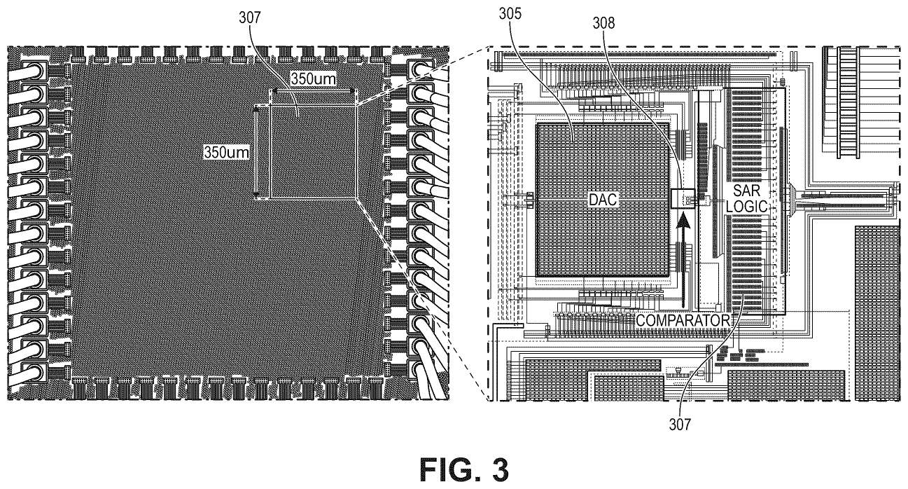

Referring now to FIG. 3, shown is a 10-bit SAR ADC with 2.4 fF unit capacitance is fabricated in a 65 nm CMOS process, along with the die microphotograph and layout. In some configurations, the ADC core 307 occupies an area of 350 μm by 350 μm and consumes 7.5 μW from 1V supply at 1 MHz out of which 3.5 μW is consumed by the comparator 303 and SAR logic 301, while the DAC 305 consumes 4 μW. The ADC power does not include power consumed by off-chip input and reference buffers and voltage regulators. In some configurations, the same ADC is also used as the reference ADC by running it at 100× lower speed which suppresses reference ripple and performs foreground calibration to suppress capacitor mismatch. In some configurations, the ML model is synthesized digitally and is off-chip.

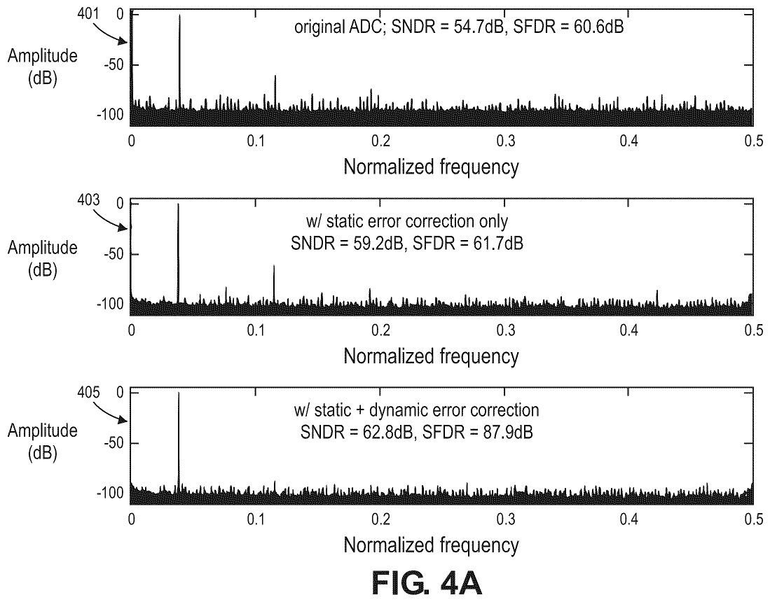

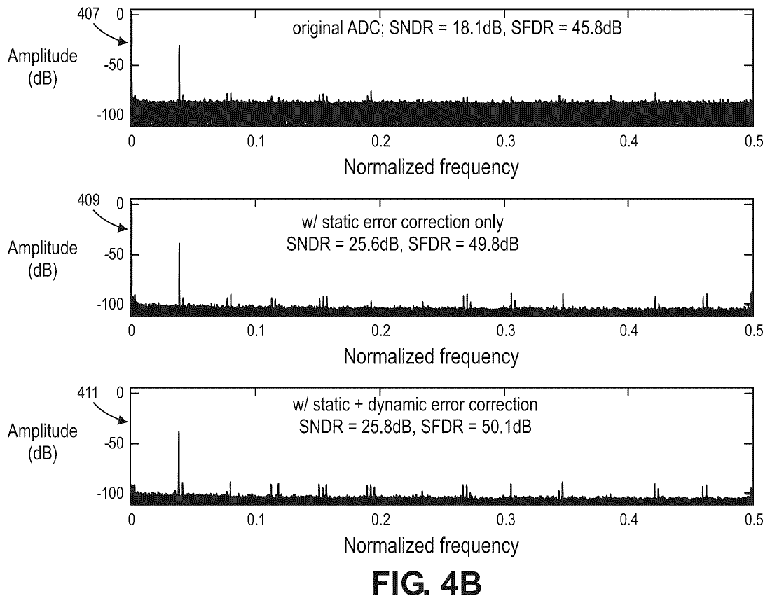

Referring now to FIGS. 4A and 4B, shown are the results of ML based error correction with large and small input signal. In some configurations, the ML model is trained at −1.1 dBFs input and tested on the other inputs. As shown in FIG. 4A, the uncorrected SAR ADC 401 is limited by noise and spurs from capacitor mismatch and reference ripple due to signal dependent voltage drop across the bond-wires. Applying static error correction 403 by using only the comparator outputs as features suppresses capacitor mismatch improves SNDR by 4.5 dB and SFDR by 1.1 dB, whereas using additional features 405 improves SNDR by 8.1 dB and SFDR by 27.3 dB for large input signal case. For the input signal case 407/409/411, the primary source of error is capacitor mismatch so using only static features and combination of static and dynamic features result in similar improvements in SNDR and SFDR.

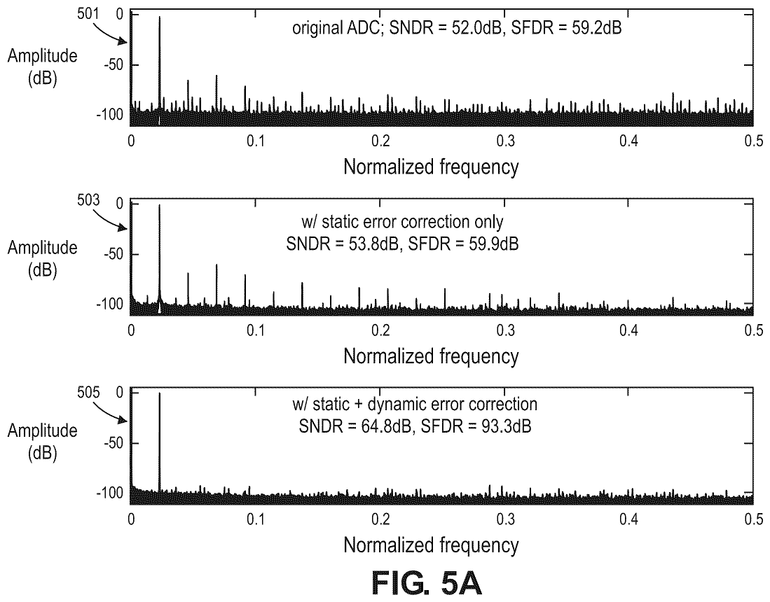

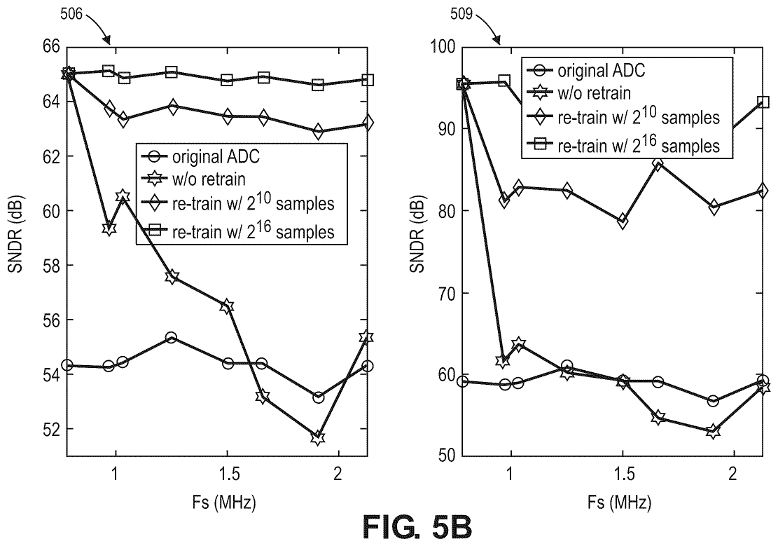

Referring now to FIG. 5A, shown is the application of ML for error correction at an Fₛ which is different from the Fₛ at which the ML model is retrained for −1.1 dBFs input. The ML model is initially trained 501 at Fₛ=0.8 MHz and then tested at Fₛ=2.1 MHz. Without re-training the ML model for Fₛ=2.1 MHz, the SNDR after ML correction 503 is improved by only 1 dB whereas the SFDR dropped by 0.8 dB. This is due to the fact that the dominant error source is reference ripple which is dynamic error and changes with Fₛ. After re-training the ML model with 2¹⁴ samples, SNDR and SFDR 505 are improved by 10.5 dB and 34.1 dB respectively compared to the uncorrected ADC.

Referring now to FIG. 5B, shown are graphs of SNDR 507 and SFDR 509 as a function of Fₛ for the ADC trained at Fₛ=0.8 MHz and tested at other Fₛ values with and without re-training. Without re-training, SNDR and SFDR drop with Fₛ and become similar or worse than that of the uncorrected ADC as Fₛ moves further away from the value at which the ML model was trained. SNDR and SFDR improve with re-training. SNDR and SFDR improve by 7.8 dB and 24 dB respectively for re-training with 2¹⁰ samples and 9.5 dB and 34.9 dB respectively for re-training with 2¹⁶ samples compared to without re-training. These results demonstrate the trade-off between error correction accuracy and re-training speed, with longer re-training time needed for correcting the ADC errors to higher accuracy.

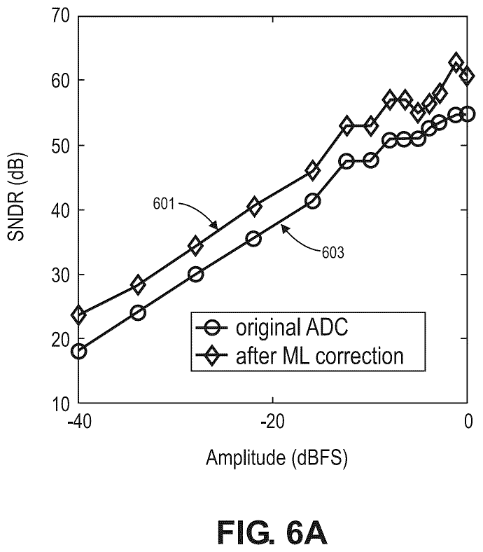

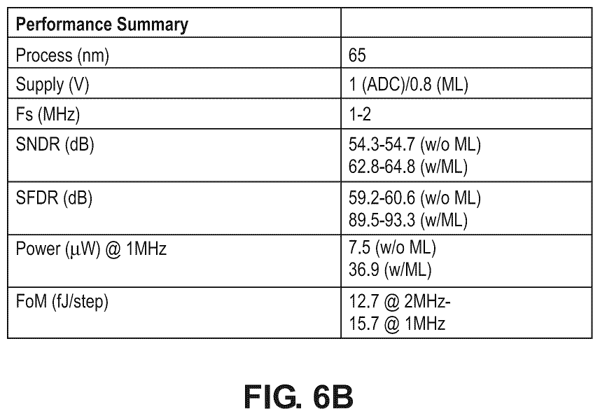

Referring now to FIG. 6A, shown are plots SNDR of the ADC versus input swing at Fₛ MHz with 603 and without 601 ML based error correction. ML improves SNDR by 8 dB or more for all input amplitudes.

Referring now to FIG. 6B, shown is a summary of the performance of an implementation in accordance with embodiments of the present disclosure. In some configurations, the ML improves SNDR by 8−10 dB and SFDR by more than 30 dB for different sampling frequencies. The uncorrected ADC consumes 7.5 mμW from 1V supply while the ML consumes 27.9 mμW from 0.8V supply. The remaining 1.5 mμW is consumed for generating features for the ML model. The ML model is digitally synthesized and its power estimated from transistor level simulation of the synthesized model. ML inference runs at ADC sampling speed and consumes 23 mμW at 1 MHz while the training happens at 10 kHz and consumes 4.9 mμW. The ML power is 3.7× the ADC power which can be explained intuitively by the fact that the ML model needs higher precision than the ADC in order to correct the ADC errors. To get to the same performance as the corrected ADC through analog scaling, the comparator power needs to increase by 10× and DAC switching power needs to increase by 4× which can increase the ADC power to 51 mμW. This estimated power calculation does not take into consideration the limits on SNDR imposed by reference ripple which may not be improved by analog scaling of comparator and DAC size. Stochastic techniques can reduce comparator and quantization noise.

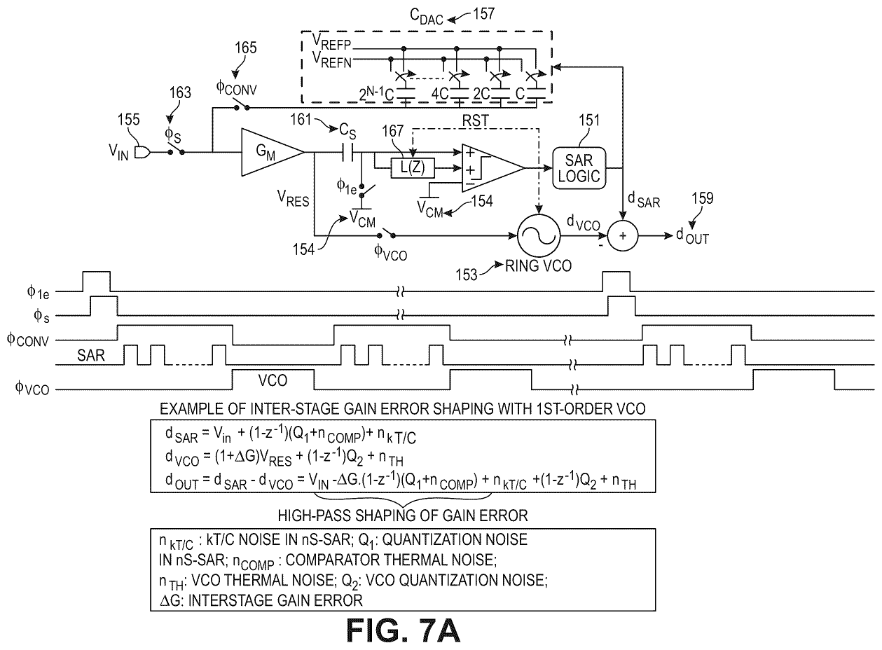

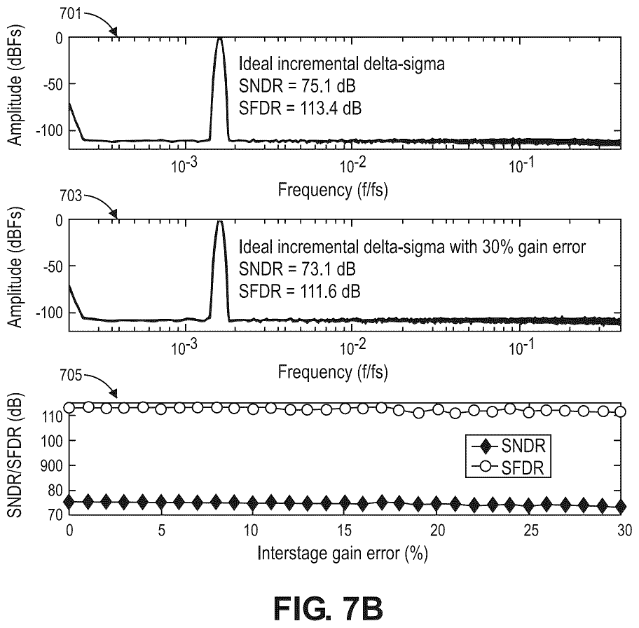

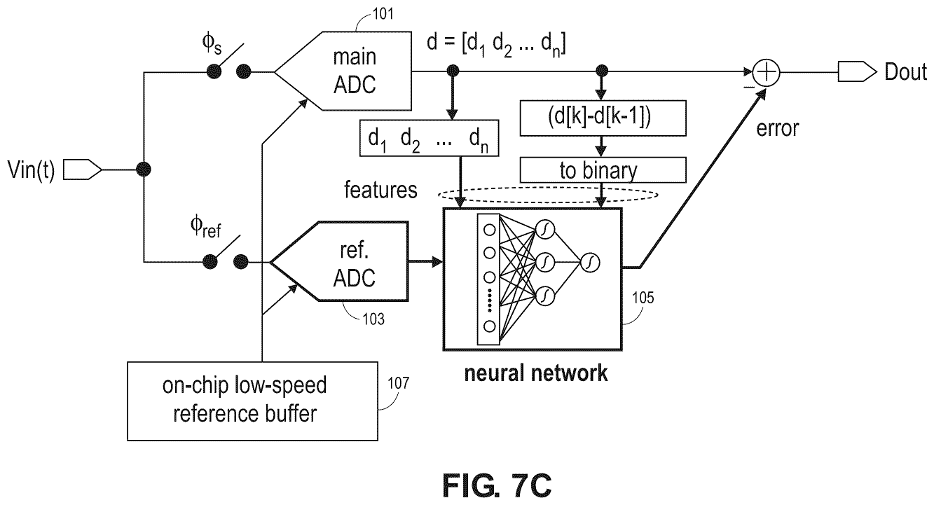

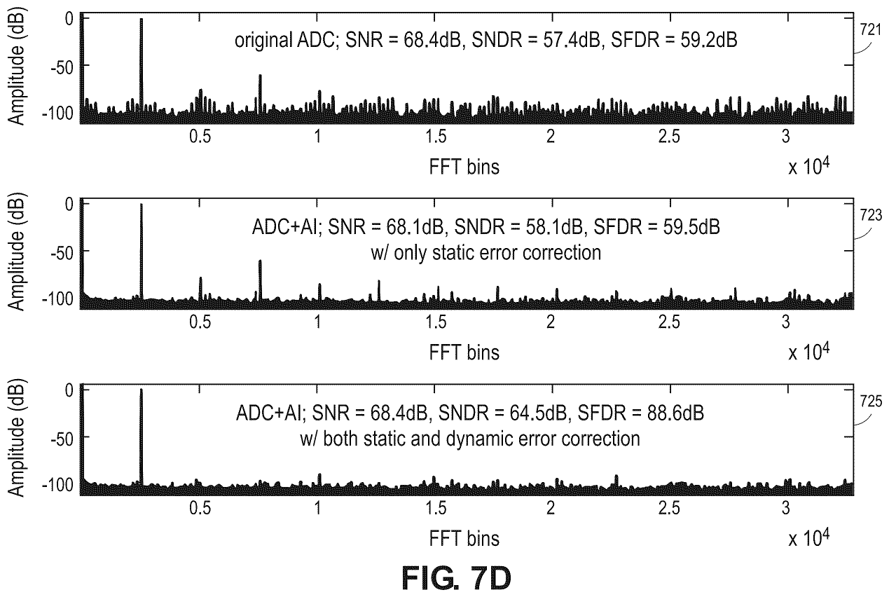

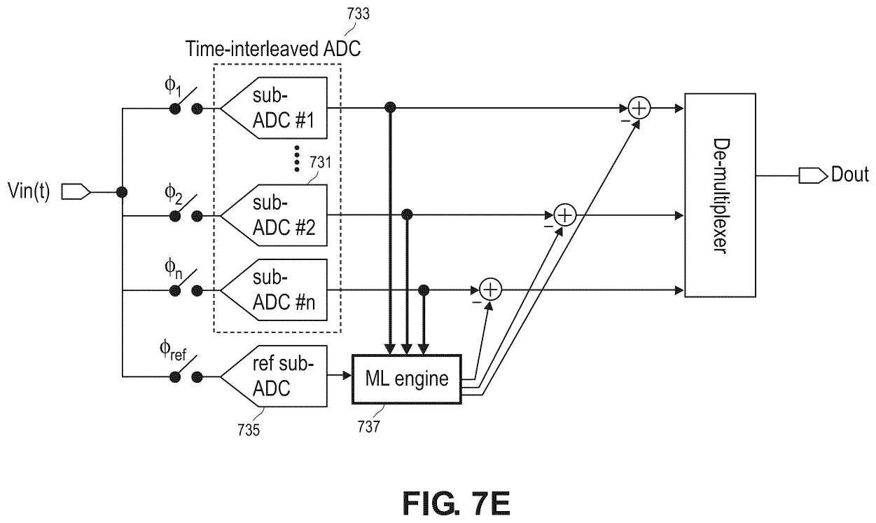

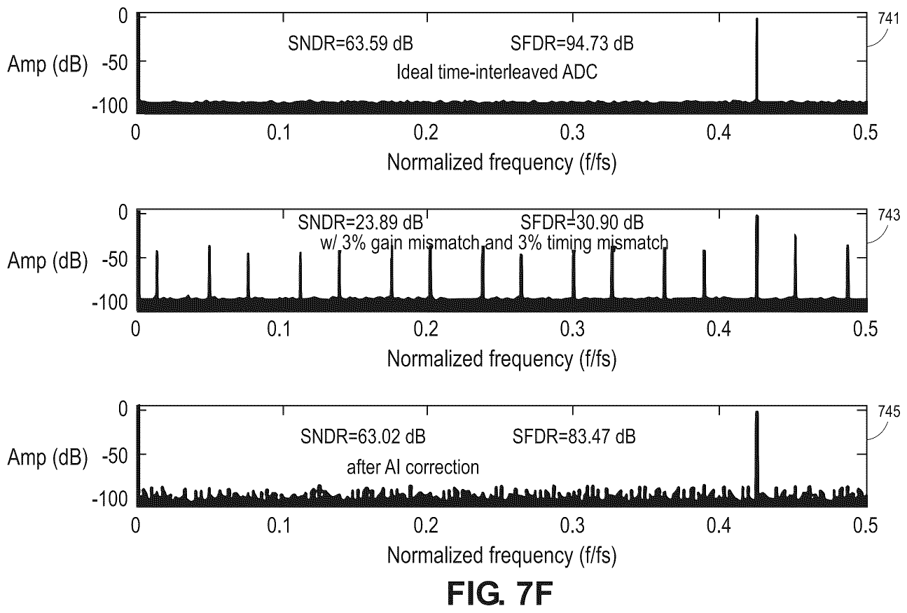

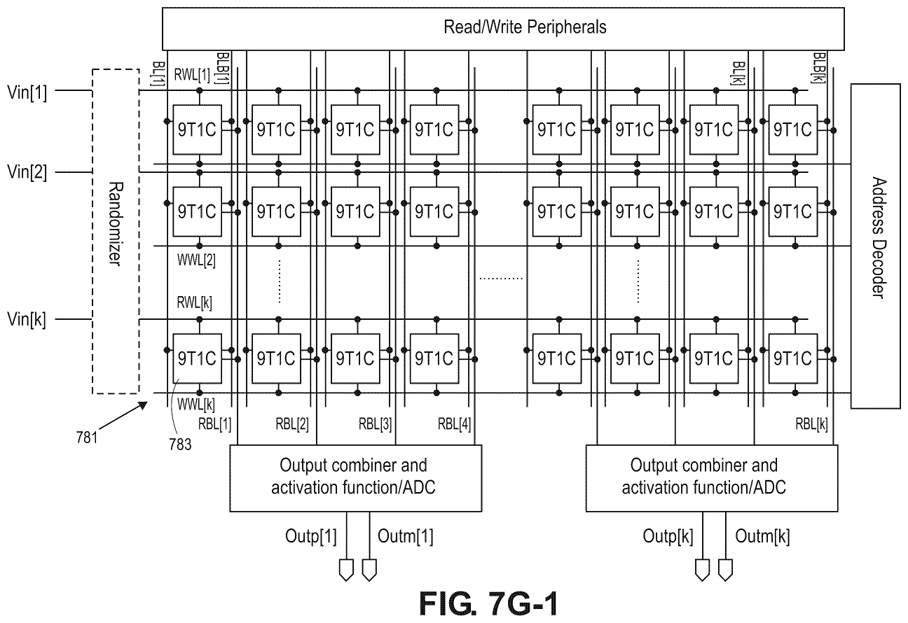

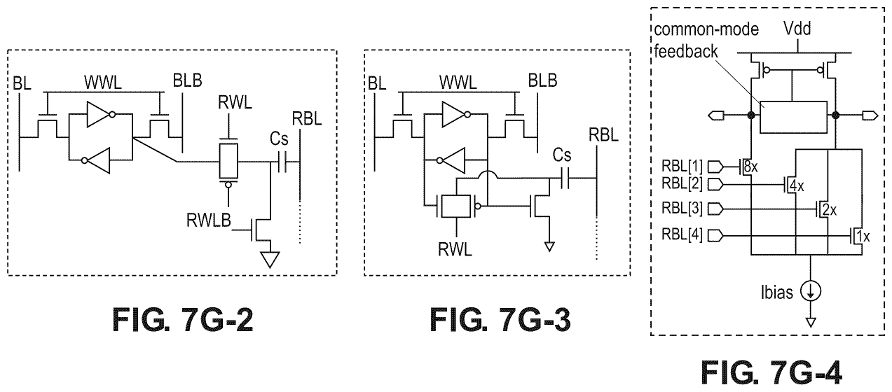

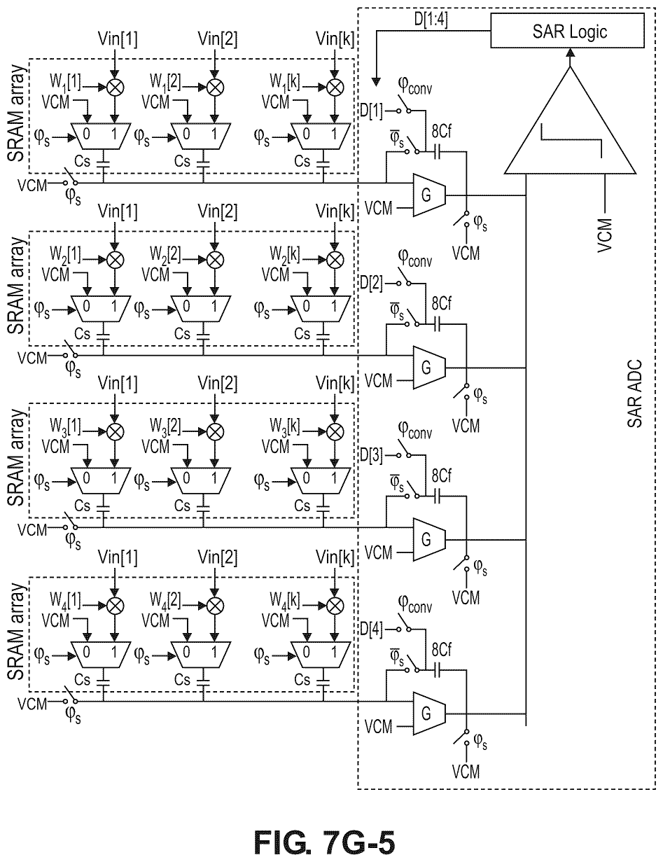

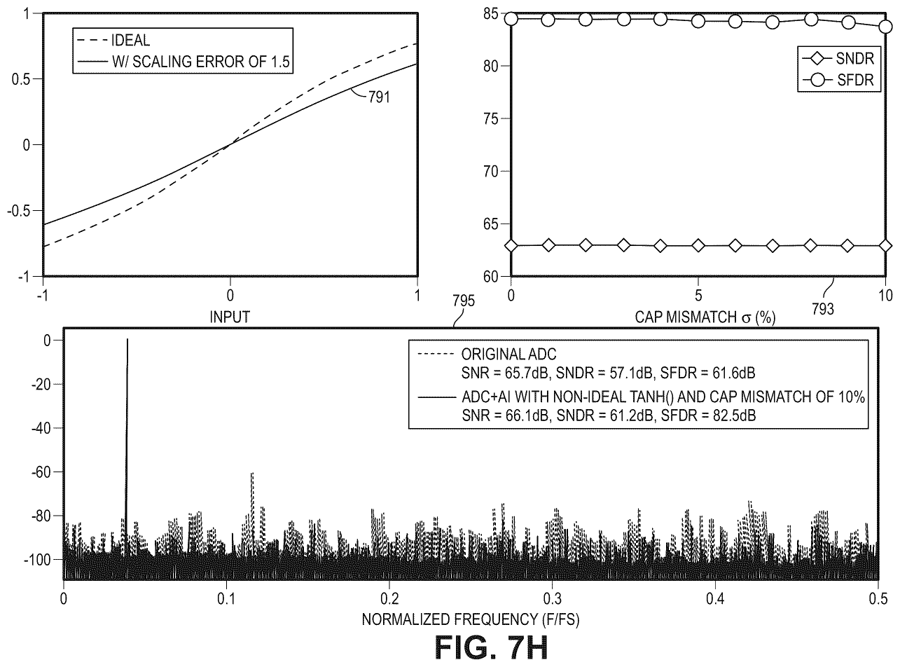

Referring now to FIG. 7A, shown is a circuit that can correct static and dynamic errors in a SAR ADC using ML. A high-resolution incremental delta-sigma ADC with NS-SAR at the first stage and VCO as the second stage is shown. Noise shaping in the NS-SAR stage high-pass shapes the interstage gain error. A low-speed (−5 MHz bandwidth) and high-resolution (ENOB >12-bit) ADC can be used as a reference ADC for supervised ML-based error correction techniques in accordance with embodiments of the present disclosure. Delta-Sigma architectures, for example, mostly digital architectures, can be used for the high-resolution and low-speed ADCs. For example, a NS-SAR 151 or a ring inverter-based VCO 153 can enable delta-sigma ADCs. The NS-SAR 151 realizes a feed forward delta-sigma modulator in which the input is fed to the input of the quantizer through an additional path (hence, feed forward). For NS-SAR, the comparator acts as the quantizer. As in a delta-sigma architecture, the quantizer output is subtracted from the input using charge redistribution in the capacitor array and the error is passed through the loop filter (L(z)) 167, which is realized as a passive integrator in embodiments in accordance with the present disclosure. The input signal 155 is also fed to the quantizer directly to realize the feed forward delta-sigma. The ring VCO 153 acts as an open-loop delta-sigma modulator. The ring VCO 153 converts the analog input 155 to frequency and then integrates that to provide a phase output. The integral of the input realizes the “sigma” operation, and the “delta” operation is performed by subtracting a previous output of VCO from the present output.

Continuing to refer to FIG. 7A, the incremental delta-sigma ADC has a low-resolution (5˜6 bits)NS-SAR 151 as first stage, and a ring VCO 153 as second stage. The signal attenuation by the NS-SAR 151 linearizes the VCO 153. The quantization error and comparator noise from NS-SAR 151 are suppressed by the combined architecture, and an additional residue amplifier is not required because the VCO stage provides inherent time-domain amplification. The VCO 153 is shielded from input common-mode V_{cm} 154 variation by the first stage NS-SAR 151, and the overall architecture is digital and scaling friendly. The NS-SAR 151 stage embeds an input buffer inside the SAR loop. Placing the buffer inside SAR loop ensures that both the input Vᵢₙ 155 and digital-to-analog converter (DAC) C_{dac} 157 see the same distortion transfer function of the buffer, thus canceling its nonlinearity in the ADC output 159. Hence, the input buffer power consumption can be low due to relaxed linearity requirements and the buffer can be a simple source follower. In some configurations, analog input is sampled on the sampling capacitor Cₛ 161 during the phase ϕₛ 163 using a bottom-plate sampling technique that prevents charge-injection error. During the ϕ_{conv} 165 phase, the DAC 157 is connected to the top-plate of the sampling capacitor and the NS-SAR 151 performs the conversion. Noise-shaping in the NS-SAR 151 is realized through an active integration filter with transfer function L(z) 167. Active integration is required to ensure that charge sampled on Cₛ 161 during ϕₛ 163 is not lost through charge-sharing. The closed-loop amplifier needed for active integration is realized using dynamic floating inverter amplifier topology that improves robustness of the amplifier against variations in operating conditions. The residue from the NS-SAR 151 is sent to the VCO stage for fine conversion, and outputs from the two stages are combined to create the overall ADC output 159. The ADC performs N conversions of each sampled input to realize delta-sigma operation with oversampling ratio of N, and the active integrator in the NS-SAR 151 and the VCO 153 are reset at the start of each sampling phase. Thus, the overall ADC acts as an incremental delta-sigma. The conversion residue from the NS-SAR 151 is sent to the VCO 153 for time-domain quantization. High-pass shaping interstage gain mismatch is accomplished since the NS-SAR high-pass shapes quantization noise of the NS-SAR 151, and any error in interstage gain is also shaped by the noise-transfer function (NTF) 167 of the NS-SAR stage.

Referring now to FIG. 7B, delta-sigma ADCs that are calibration-free 701 combine the advantages of NS-SAR and VCO architectures while achieving >12-bit ENOB energy-efficiency. The architecture of the high-resolution reference ADC is robust against interstage gain error 705 because of the way the outputs (dₛₐᵣ and d_{vco}) are combined. Specifically, the gain error ΔG 703 is shaped by the multiplier term (1−z⁻¹)(Q₁+n_{comp}) where Q₁ is the quantization noise in NS-SAR, and n_{comp} is the comparator thermal noise.

Referring now to FIG. 7C shown is a single-channel ADC with ML-based error correction in accordance with embodiments of the present disclosure. A SAR ADC can be used for the main ADC 101, and the incremental delta-sigma ADC described herein can be used as the reference ADC 103. The reference ADC 103 is used to train the neural network 105 for correction of static and dynamic errors in the main ADC 101. The reference ADC 103 runs at M times lower speed than the main ADC 101. Thus, outputs of the main ADC 101 and the reference ADC 103 align every M-th sample of the main ADC 101. For the aligned samples, the neural network 105 uses features derived from the main ADC 101 output and learns the error between the two ADCs. While the training happens every M sample, inference happens every sample, i.e., the neural network 105 uses features derived from main ADC output and adds a correction term each cycle. Both ADCs use a low-speed reference buffer 107 that generates a reference voltage for the NS-SAR in the reference ADC 103. Static errors in main ADC 101 can arise from, for example, but not limited to, capacitor mismatches in the DAC (that is inside the ADC). A circuits-informed ML approach uses a custom representative feature set derived from the main ADC circuit to reduce inaccuracy of the ML algorithm to a very low amount, for example, but not limited to, <0.001%. Static error mismatches are learned by the ML model through the binary bits of the main ADC output being used as features. The mismatch error of each capacitor is additive and added to the ADC output only if the corresponding digital output bit is 1. Thus, the ML model can learn mismatch error associated with each capacitor by using the binary output bit stream as features.

Dynamic errors can arise from, for example, but not limited to, reference ripple, comparator and DAC kick-back, and charge injection error in the sampling switches Φₛ and Φ_{ref}. Dynamic error is a function of input amplitude and frequency, which is captured from the digital derivative of the output of the main ADC 101 by subtracting the previous output from the current output. Features are converted to binary ‘0/1’ numbers for the ML training/inference.

Referring now to FIG. 7D, shown are results that demonstrate the ML-based static and dynamic error correction from a 12-bit, 65 nm SAR ADC test-chip. In the example, the original SAR ADC 721 has spurs at 0.5, 0.75 in the spectrum due to capacitor mismatches, as well as ripple in the reference voltage. In this example, a 13-bit SAR ADC is used as the reference ADC which runs at 1/10^{th} speed of the main ADC. Also in the example, a two-layer neural network is used with a hidden layer with 10 neurons, and tanh activation in the hidden layer. The output layer uses linear regression with a single neuron. The neural network corrects capacitor mismatches (static error) if the binary bits of the main SAR ADC output are used as features for training, and corrects both static and dynamic errors if the derivative of main ADC output is added to the feature set. In this example, 1024 samples are captured to ensure training convergence. SNDR and SFDR results from the original ADC 721 to the ADC with static error correction 723 are similar because, with static error correction, the capacitance mismatch is corrected and not the dominant error source. With both static and dynamic error correction 725, the neural network improves SNDR by 7 dB and SFDR by >29 dB.

Since the accuracy with which errors in the main ADC can be corrected depends on the resolution of the reference ADC, it is critical to ensure that the reference ADC maintains a threshold accuracy, for example, but not limited to, >12-bit ENOB, when it is used for training the neural network. Coupling between reference and main ADCs may degrade performance of the reference ADC. To reduce coupling and kickback through the shared input lines, both ADCs can use individual embedded input buffers that isolate the sampling capacitors of each ADC from kickback from the other ADC. Another option is that the main ADC can use an out-of-loop front-end input buffer, instead of an embedded buffer, to isolate the DAC and sampling capacitors of the reference ADC from kickbacks in the main ADC. The neural network can correct for nonlinearity in the front-end input buffer in the main ADC. To prevent coupling through either input lines and/or reference lines, both ADCs can use separate low-speed reference buffers to improve linearity of reference ADC. Coupling that results from the substrate can be mitigated in layout through guard rings and deep n-wells for the reference ADC.

The neural network trains in the background, at the speed of the reference ADC, to correct dynamic errors that vary with amplitude and frequency content of the input signal. In some configurations, a 2-layer neural network with 10 hidden neurons is used. Further reduction in size can be obtained through hyper-parameter optimization and weight pruning. Storage requirements for on-chip training can be reduced by enabling the neural network to learn online, i.e., the training happens with new predictor and response data each time. In some configurations, the chip stores the previous ADC output (for feature generation), but does not need to store the training dataset for iterative training over multiple epochs. In some configurations, online training allows the use of ADAM or RMSprop optimizers with individually adaptive learning rates for the weights.

Referring now to FIG. 7E, shown is a schematic of a time-interleaved ADC with ML-based calibration for correcting a mismatch between sub-ADCs 731, in accordance with embodiments of the present disclosure. In some configurations, the time-interleaved ADC 733 uses supervised ML for correction of mismatch errors between the sub-ADCs 731. If the n sub-ADCs 731 are operating at sampling frequency of Fₛ, the time-interleaved ADC 733 operates at nFs. In some configurations, the reference sub-ADC 735 runs at a sampling frequency of nFs/m, where m and n are mutually prime integers. The choice of sampling frequency ensures that consecutive outputs of the reference sub-ADC 735 aligns with a different sub-ADC 731 at each sample and generates ground truth for training the ML engine 737 to correct errors in each sub-ADC 731. The ML engine 737 includes n neural networks that are dedicated to error correction in each of the n sub-ADCs 731. In some configurations, the target performance for the time-interleaved ADC 733 is 10-bit ENOB at bandwidth ˜10 GHz. If the bandwidth of each sub-ADC 731 is 1 GHz, ˜10 sub-ADCs 731 are time-interleaved, and the reference sub-ADC 735 operates at ˜700-800 MHz bandwidth and has ˜11-bit ENOB to meet the time-interleaved ADC 733 specification. Gain error in a SAR ADC is primarily due to static element mismatch between capacitors in its DAC. Each sub-ADC 731 has different gain errors which creates gain mismatch. Offset error in each sub-ADC 731 is due to mismatches in the comparator which varies between sub-ADCs 731 and results in offset mismatch. Timing mismatch arises due to mismatches in routing sampling clock phases to each sub-ADC 731 which shifts the sampling instants in each sub-ADC 731 from an ideal sampling instant. Bandwidth mismatch is primarily due to mismatches between the track-and-hold in each sub-ADC 731 which contributes to additional gain and timing mismatches. The reference sub-ADC 735 itself has gain, offset, and timing errors, the ML engine 737 ensures that all the sub-ADCs 731 have the same errors as the reference sub-ADC 735 which suppresses mismatches between the sub-ADCs 731.

Continuing to refer to FIG. 7E, the ML engine 737 has n neural networks dedicated to each of the n sub-ADCs 731. When the k-th sub-ADC 731 is aligned with the reference sub-ADC 735, the k-th neural network uses features extracted from the k-th sub-ADC output and learns the error between reference sub-ADC and the k-th sub-ADC output, which is used to correct the sub-ADC outputs in future sampling instants. The features used to train the neural network are current and several prior outputs of the sub-ADC 731 and derivatives of these outputs which are calculated by subtracting one cycle delayed output from current output, with all features applied to the neural networks in binary format. Difference between the outputs of the sub-ADC 731 and reference sub-ADC 735 helps the neural network learn gain and offset error, while the timing error is extracted from the derivatives of sub-ADC outputs. Bandwidth error manifests as gain and timing error and is captured from the current and prior samples of the sub-ADC output.

Referring now to FIG. 7F, shown are the model results from executing a configuration in accordance with embodiments of the present disclosure to demonstrate correction of gain and timing mismatch error in a time-interleaved ADC. In some configurations, an 11-bit, 16-channel time-interleaved ADC with the reference sub-ADC running at 16 Fs/17 is used where each sub-ADC runs at Fₛ. A time-interleaved ADC 741 without any mismatches has an SNDR of 63.59 dB and SFDR of 94.73 dB. With introduction of 3% gain mismatch and 3% timing mismatch between the sub-ADCs, the time-interleaved ADC 743 exhibits spurs and SNDR and SFDR are reduced to 23.89 dB and 30.9 dB respectively. In some configurations, for ML correction 741, the features used are current and previous 9 outputs from the sub-ADC as well as their derivatives. In some configurations, the ML engine includes 16 neural networks which are trained independently and learn the error of each sub-ADC with respect to the reference sub-ADC. Each neural network uses a two-layer architecture with a hidden layer with 10 neurons, and tanh activation in the hidden layer. The output layer uses linear regression with a single neuron. In some configurations, the ML engine uses 1024 samples for training convergence and improves SNDR by 39 dB and SFDR by >50 dB.

Continuing to refer to FIG. 7F, other configurations include a reference sub-ADC that is isolated from the other sub-ADCs to address a possible degradation of the output by kickback through input or reference voltage lines from the other sub-ADCs. This configuration can be achieved by having dedicated input and reference voltage buffers for the reference sub-ADC. The other sub-ADCs can include embedded input buffers for low power consumption and can share a few (2-3) reference voltage buffers between themselves which reduces buffer power consumption by ˜5× compared to having dedicated GHz-speed reference voltage buffers for each sub-ADC. Sharing reference voltage buffers can result in dynamic errors in the sub-ADCs that are corrected by the ML engine. A single-channel GHz ADC can be a suitable choice for reference sub-ADC. In some configurations, a lower-speed (˜300-400 MHz bandwidth) reference sub-ADC without ML error correction can be used.

Continuing to refer to FIG. 7F, in configurations in accordance with embodiments of the present disclosure, the neural network has a higher precision than the ADC while operating at the same speed as the ADC. An on-chip neural network has a lower power consumption than the uncompensated ADC. SRAM-CIM based neural networks compute a MAC result in the analog domain, and read-out ADC digitizes MAC outputs from the SRAM arrays. In some configurations, to reduce the number of read-out ADCs used, analog circuits are used for activation functions so that data conversion may not be used between the layers of the neural network, and 1 read-out ADC is used to digitize the output layer's output. In some configurations, the output of the neural network is the estimated error in the main ADC. Thus, the read-out ADC for the neural network has a relaxed linearity and resolution requirement compared to the main ADC.

Referring now to FIG. 7G-1, shown is an exemplary schematic of a switched-capacitor SRAM-CIM array 781 in accordance with embodiments of the present disclosure. In the exemplary schematic, the neural network weights are stored in the SRAM cell 783 along with a sign bit as most significant bit (MSB) which allows storing both positive and negative weights.

Referring now to FIGS. 7G-2, 7G-3, 7G-4, and 7G-5 shown are the SRAM cell schematics for the hidden layer (FIGS. 7G-2 and 7G-4) and the output layer (FIG. 7G-3 and 7G-5). Inputs to the hidden layer are binary features (‘0/1’) which are sampled on the capacitors inside the SRAM cells 753 if the SRAM cell 753 is holding a ‘1’, otherwise the capacitor is discharged. The SRAM cell 753 in the output layer accepts analog output of the tanh( ) activation circuits from the hidden layer, and the capacitor in the SRAM cell 753 is charged with the analog input through a CMOS switch or discharged during the sampling phase depending on whether the SRAM cell 403 is storing ‘1’ or ‘0’ respectively. The MAC outputs are calculated in charge-domain and stored in read bit lines (RBL). The multi-bit output MAC outputs are summed with appropriate binary weights in current-domain for hidden layer (FIG. 7G-4), and in charge-domain using an amplifier for the output layer (FIG. 7G-5). The binary weighted addition techniques do not attenuate the MAC output and improve signal-to-noise ratio (SNR) compared to binary weighted addition through passive charge sharing between SRAM capacitors and additional capacitor banks. As shown in FIG. 7G-4, a common-source amplifier realizes tanh( ) activation. Outputs from the amplifiers in the hidden layer drive the SRAM cells 753 in the output layer without requiring additional data conversion.

Referring now to FIG. 7G-5, shown is a read-out circuit for an exemplary output layer with 4-bit weights. When the sampling phase is over, the multi-bit MAC outputs are combined using switched-capacitor amplifiers with binary weighted feedback capacitors, and the amplifier outputs are digitized by a SAR ADC. Hence, the switched-capacitor amplifiers double-up as pre-amplifiers for the read-out ADC such that the read-out ADC sees a full swing input. The feedback capacitors in the amplifiers are re-used as DAC capacitors in the SAR ADC as shown in FIG. 7G-5. Pre-amplification enables low-resolution read-out ADC and also prevents attenuation of MAC outputs, thus improving energy efficiency of the neural network and enabling its on-chip realization.

Referring now to FIG. 7H, shown are results that demonstrate the relative robustness of the ML error correction in the presence of errors in the analog implementation of tanh( ) activation and capacitor mismatch. Tests are performed to examine the effect of a non-ideal activation function 791 and capacitor mismatch 793 on the accuracy of ADC error correction. The transfer function of the analog tanh( ) deviates from the actual tanh( ) due to transistor mismatches and manifests as scaling error of the tanh( ) argument which shifts the transfer function as shown in FIG. 7H. Capacitor mismatches in the SRAM cells effectively perturb model weights and introduce errors in the ML output. However, the ML model has inherent tolerance against errors in both activation transfer function and capacitor mismatches since the on-chip ML training uses the ML output containing errors to update the model weights. This is shown in FIG. 7H. The ADC SNDR and SFDR 795 reduce by less than 2 dB even with scaling error of 1.5 in tanh( ) activation and 10% mismatch in SRAM capacitors.

In some configurations, an on-chip neural network that provides high-precision, high-speed output and low power consumption can be achieved by precision of MAC computations through reducing capacitor mismatch by applying dynamic element matching (DEM) techniques from a data converter field. Since training happens on-chip, DEM can be used to randomize the order in which the inputs and weights are applied to the SRAM array as shown in FIG. 7G-1. Further, charge-injection errors can be addressed through use of a randomizer placed in the input path. A randomizer can be incorporated inside the SRAM address decoder to change both input and weight positions inside the array such that the overall MAC computations are unaffected. Charge-injection errors in the SRAM cells can be addressed through a bottom-plate sampling technique. Still further, an amplifier transfer function shift can be corrected by digitally tunable resistors connected to the source nodes of the input transistors.

The neural network performs MAC computations in analog domain with a read-out ADC digitizing the final output. In analog computations, there are trade-offs between noise, power, and speed. Noise in the switched-capacitor circuits (SRAM cells and pre-amplifiers in the output layer) can be reduced by increasing capacitance. The capacitor values can be chosen to optimize the noise-speed-power trade off. Noise power in the amplifiers for tanh( ) activation is inversely proportional to the speed and power consumption of the amplifier. The amplifier values can be chosen to optimize energy efficiency and accuracy.

The read-out circuit can digitize output of the neural network with higher precision than the main ADC that is calibrated by the neural network. The neural network outputs can be amplified, digitized by a low-resolution (˜4-5 bit) SAR ADC, and digitally scaled down again. In some configurations, a floating inverter topology can be used for the amplifier. Such an amplifier has a relatively constant gain which may not vary with operating conditions, and low open-loop gain which can result in closed-loop gain errors which can be corrected in the digital backend after the ADC.

The circuits described herein can be designed and fabricated through multi-wafer prototyping programs, for example. In some configurations, a low-speed ADC has a power consumption <200ρW at 5 MHz bandwidth and >12-bit ENOB (energy-efficiency <5 fJ/conv-step). A high-speed single-channel ADC has power consumption <1500 mW that includes power consumed by input and reference buffers and on-chip ML at 1 GHz bandwidth and 12-bit ENOB (energy-efficiency <200 fJ/conv-step). A time-interleaved ADC has power consumption <6000 mW that includes power consumed by input and reference buffers and on-chip ML at 10 GHz bandwidth and 10-bit ENOB (energy-efficiency <300 fJ/conv-step). An on-chip ML has error correction accuracy >99.999%, convergence time <1 ms, inference speed of 1 GHz with power consumption of 50 mW for single-channel ADC and 500 mW for time-interleaved ADC.

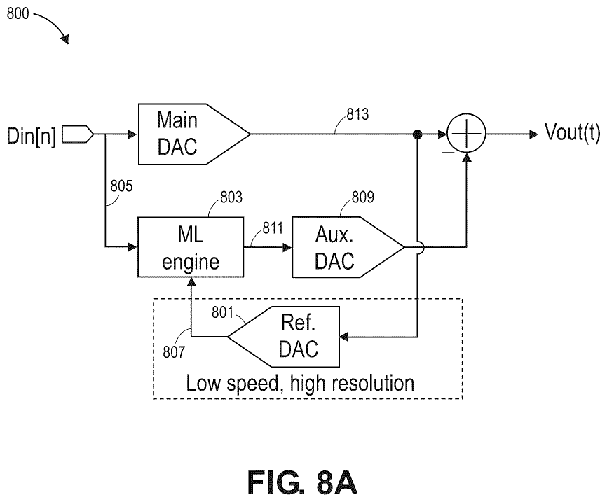

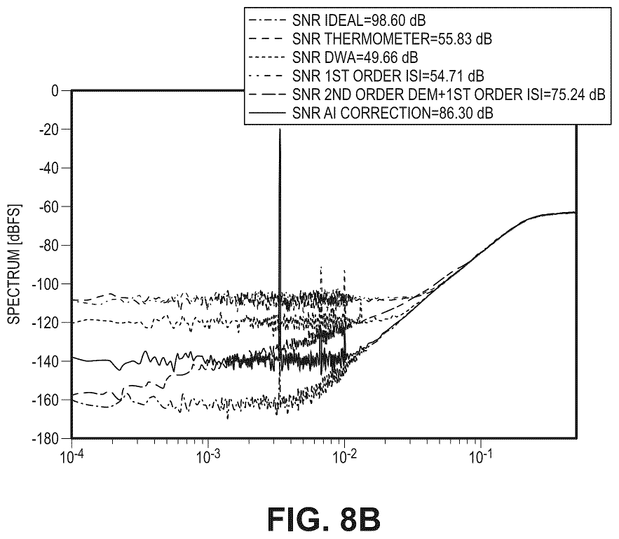

Referring now to FIG. 8A, with respect to ML-based error correction for a specific type of DAC—continuous time DAC—that includes non-linearities due to static element mismatch as well as inter-symbol interference (ISI), existing digital calibration techniques try to minimize both static mismatch and ISI through dual loops that try to maintain a constant up/down transition rate to suppress nonlinearity due to ISI while selecting the least used DAC elements to high-pass shape static mismatch error. For a continuous time DAC, as in ADC error correction techniques, a low-speed reference ADC 801 is used to digitize the DAC outputs every M cycles of the DAC. The ADC outputs 807 are compared with the DAC inputs 805 at aligned sampling instants and the ML model 803 is trained to learn the error between the DAC input 805 and reference ADC output 807 which captures static mismatch and dynamic errors such as, for example, but not limited to, inter-symbol interference (ISI) errors. In configuration 800, the ML model 803 uses, for example, but not limited to, the thermometer coded DAC input and up-transition density as features to learn static mismatch and dynamic errors respectively. An auxiliary DAC 809 is used to convert the ML outputs 811 to an analog signal and subtract from the main DAC output 813 to perform error correction. In contrast to existing digital error correction techniques, the proposed error calibration technique does not add delay to the DAC path, and uses a neural network and a low-speed SAR ADC. To compare the error correction for the continuous time DAC, a 16-element, 3^{rd}-order DAC with oversampling rate (OSR) of 50 is used. In configuration 800, the DAC elements can have static mismatch with zero mean and 1% standard deviation, and ISI error with 1% standard deviation. Thermal noise can be added to limit SNR of ideal DAC to be 98 dB at OSR of 50. The ML model uses the same architecture as the neural network used to correct errors in the single-channel ADC described herein. In some configurations, the ML model 803 is trained with input frequency at Fₛ=1515 and tested with input frequency at Fₛ=300.

Referring now to FIG. 8B, the simulation results of techniques using various SNRs are shown. Thermometer coding and first-order ISI shaping suppresses ISI error but suffers from element mismatch, while data weighted averaging high-pass shapes element mismatch but suffers from ISI error, and all these techniques have low SNR and low SFDR. Combination of static mismatch and ISI error shaping can improve SNR and SFDR, and the ML-based error correction as shown in configuration 800 (FIG. 8A) achieves a suppression of static mismatch and ISI error and improves the SNR.

Systems, methods, and computer program products are provided. In the detailed description herein, references to “various embodiments,” “one embodiment,” “an embodiment,” “an example embodiment,” etc. indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to ‘at least one of A, B, and C’ or ‘at least one of A, B, or C’ is used in the claims or specification, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Although the disclosure includes a method, it is contemplated that it may be embodied as computer program instructions on a tangible computer-readable carrier, such as a magnetic or optical memory or a magnetic or optical disk. All structural, chemical, and functional equivalents to the elements of the above-described various embodiments that are known to those of ordinary skill in the art are expressly incorporated herein by reference and are intended to be encompassed by the present claims. Moreover, it is not necessary for a device or method to address each and every problem sought to be solved by the present disclosure for it to be encompassed by the present claims. Furthermore, no element, component, or method step in the present disclosure is intended to be dedicated to the public regardless of whether the element, component, or method step is explicitly recited in the claims. No claim element is intended to invoke 35 U.S.C. § 112(f) unless the element is expressly recited using the phrase “means for” or “step for”. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In re Nuijten to fall outside the scope of patentable subject matter under 35 U.S.C. § 101.

1. A method for providing analog-to-digital conversion using a first analog-to-digital converter (ADC) and a second ADC, the method comprising:
executing iterated operations including:
generating ground truth by the first ADC;
training a machine learning (ML) model at each of the iterated operations using the ground truth and an uncorrected output from the second ADC to learn to predict errors of the second ADC at sampling points that the first ADC and the second ADC have in common; and
modifying the uncorrected output based on the errors predicted by the ML model to produce a corrected output.

2. The method of claim 1, wherein modifying the uncorrected output comprises:
computing a difference between the errors and the uncorrected output.

3. The method of claim 1, wherein the first ADC comprises:
a low speed (≤5 MHz), high resolution (≥11 bits) ADC.

4. The method of claim 1, wherein learning to predict errors comprises:
minimizing a loss function.

5. The method of claim 4, wherein minimizing the loss function comprises:
squaring a difference between the uncorrected output and the ground truth; and
dividing the squared difference by two.

6. The method of claim 1, wherein the ML model comprises:
a hidden layer; and
an output layer.

7. The method of claim 6, wherein the output layer comprises:
one neuron performing linear regression.

8. The method of claim 6, wherein the hidden layer comprises:
up to ten neurons; and
an activation function.

9. The method of claim 8, wherein the activation function comprises:
tanh, ReLU, leaky ReLU, or Softmax.

10. The method of claim 1, wherein the second ADC comprises:
successive approximation register (SAR) logic.

11. An analog-to-digital converter (ADC) system executing iterated operations, the ADC system comprising:
a first ADC generating ground truth;
a second ADC producing a corrected output; and
a machine learning (ML) model trained at each of the iterated operations using the ground truth and an uncorrected output from the second ADC, the trained ML model configured to predict errors of the second ADC at sampling points that the first ADC and the second ADC have in common,
wherein the second ADC modifies the uncorrected output based on the errors predicted by the ML model to produce the corrected output.

12. The system of claim 11, wherein the corrected output comprises:
a difference between the errors and the uncorrected output.

13. The ADC system of claim 11, wherein the first ADC comprises:
a low speed (≤5 MHz), high resolution (≥11 bits) ADC.

14. The ADC system of claim 11, wherein the training comprises:
minimizing a loss function.

15. The ADC system of claim 14, wherein minimizing the loss function comprises:
squaring a difference between the uncorrected output and the ground truth; and
dividing the squared difference by two.

16. The ADC system of claim 11, wherein the ML model comprises:
a hidden layer; and
an output layer.

17. The ADC system of claim 16, wherein the output layer comprises:
one neuron performing linear regression.

18. The ADC system of claim 16, wherein the hidden layer comprises:
up to ten neurons; and
an activation function.

19. The ADC system of claim 18, wherein the activation function comprises:
tanh, ReLU, leaky ReLU, or Softmax.

20. The system of claim 11, wherein the second ADC comprises:
successive approximation register (SAR) logic.
